(19) United States
(12) Patent Application Publication
(10) Pub. No.: US 2013/0040408 A1
(43) Pub. Date: Feb. 14, 2013

(54) METHOD OF FABRICATING RESISTANCE VARIABLE MEMORY DEVICE AND DEVICES AND SYSTEMS FORMED THEREBY

(71) Applicants: KyungTae Nam, Suwon-si (KR); Ki Joon Kim, Hwaseong-si (KR); Youngnam Hwang, Hwaseong-si (KR)

(72) Inventors: KyungTae Nam, Suwon-si (KR); Ki Joon Kim, Hwaseong-si (KR); Youngnam Hwang, Hwaseong-si (KR)

(21) Appl. No.: 13/569,425

(22) Filed: Aug. 8, 2012

(30) Foreign Application Priority Data
Aug. 11, 2011 (KR) 10-2011-0080214

(51) Int. Cl. H01L 21/8239

(52) U.S. Cl. 438/3; 438/238; 257/E21.645

(57) ABSTRACT

An exemplary method of forming a variable resistance memory may include forming first source/drain regions in a substrate, forming gate line structures and conductive isolation patterns buried in the substrate with the first source/drain regions interposed therebetween, and forming lower contact plugs on the first source/drain regions. The forming of lower contact plugs may include forming a first interlayer insulating layer, including a first recess region exposing the first source/drain regions adjacent to each other in a first direction, forming a conductive layer in the first recess region, patterning the conductive layer to form preliminary conductive patterns spaced apart from each other in the first direction, and patterning the preliminary conductive patterns to form conductive patterns spaced apart from each other in a second direction substantially orthogonal to the first direction.

### CROSS-REFERENCE TO RELATED APPLICATIONS

This U.S. non-provisional patent application claims priority under 35 U.S.C. §119 to Korean Patent Application No. 10-2011-0080214, filed on Aug. 11, 2011, in the Korean Intellectual Property Office, the entire contents of which are hereby incorporated by reference.

### BACKGROUND OF THE INVENTION

Exemplary embodiments in accordance with principles of inventive concepts relate generally to semiconductor devices, and more particularly, to variable resistance memory devices and methods of fabricating the same.

For decades, electronic devices have steadily increased their performance and reliability, at least in part, by reducing the size of features in their circuits and thereby dramatically increasing device density. Memory devices are often at the vanguard of improvements in device density. However, as device densities increase, equipment and facility costs increase at an accelerating rate. A system and method that enables increases in integrated circuit density would therefore be highly desirable.

### SUMMARY

Exemplary embodiments in accordance with principles of inventive concepts provide methods of fabricating variable resistance memory devices with a high integration density.

Other exemplary embodiments in accordance with principles of inventive concepts provide methods of fabricating high density variable-resistance memory devices with ease.

According to exemplary embodiments in accordance with principles of inventive concepts, a method of fabricating a variable resistance memory device may include forming first source/drain regions in a substrate, forming gate line structures and conductive isolation patterns buried in the substrate with the first source/drain regions interposed therebetween, and forming lower contact plugs on the first source/drain regions. The forming of the lower contact plugs may include forming a first interlayered insulating layer including a first recess region exposing the first source/drain regions adjacent to each other in a first direction, forming a conductive layer in the first recess region, patterning the conductive layer to form preliminary conductive patterns spaced apart from each other in the first direction, and patterning the preliminary conductive patterns to form conductive patterns spaced apart from each other in a second direction substantially orthogonal to the first direction.

In exemplary embodiments in accordance with principles of inventive concepts, the forming of the lower contact plugs may further include forming an insulating layer on the conductive layer.

In exemplary embodiments in accordance with principles of inventive concepts, the forming of the preliminary conductive patterns may include a spacer forming process, in which the insulating layer may be patterned using a dry etching process.

In exemplary embodiments in accordance with principles of inventive concepts, forming the insulating layer may include forming a multi-layered structure including an oxide layer on the conductive layer and an oxidation-preventing layer between the conductive layer and the oxide layer.

In exemplary embodiments in accordance with principles of inventive concepts, the oxidation-preventing layer may include a silicon nitride layer.

In exemplary embodiments in accordance with principles of inventive concepts, the conductive isolation pattern may be provided between the first source/drain regions adjacent to each other in the first direction, and an upper portion of the conductive isolation pattern may be etched during the forming of the preliminary conductive patterns.

In exemplary embodiments in accordance with principles of inventive concepts, the lower contact plugs adjacent to each other with the conductive isolation patterns interposed therebetween may be disposed to have mirror symmetry. In some embodiments, the symmetry is about a plane bisecting the conductive isolation patterns and substantially perpendicular to a plane formed by the bottom surface of the substrate.

In exemplary embodiments in accordance with principles of inventive concepts, the method may further include forming a first metal silicide between the conductive layer and the first source/drain regions.

In exemplary embodiments in accordance with principles of inventive concepts, the method may further include forming second source/drain regions in the substrate between the gate line structures, and forming source line patterns on the second source/drain regions to extend along the gate line structures.

In exemplary embodiments in accordance with principles of inventive concepts, the source line patterns may be formed in trenches provided in the first interlayered insulating layer, and the lower contact plugs may be formed before the forming of the source line patterns.

In exemplary embodiments in accordance with principles of inventive concepts, the method may further include forming a device isolation layer in the substrate to cross the gate line structures. The second source/drain regions may be spaced apart from each other in the second direction by the device isolation layer, and the second source/drain regions separated from each other in the second direction may be electrically connected to each other by the source line patterns.

In exemplary embodiments in accordance with principles of inventive concepts, the method may further include forming a source connection line electrically connecting the source line patterns with each other.

In exemplary embodiments in accordance with principles of inventive concepts, at least portion of the conductive isolation patterns may be formed using the process of forming the gate line structures.

In exemplary embodiments in accordance with principles of inventive concepts, the method may further include forming conductive connection pattern electrically connecting the conductive isolation patterns with each other.

In exemplary embodiments in accordance with principles of inventive concepts, the method may further include forming variable resistance structures on the lower contact plugs, respectively. Each of the variable resistance structures may include a magnetic tunnel junction.

In exemplary embodiments in accordance with principles of inventive concepts, a semiconductor device includes gate line structures and conductive isolation patterns buried in a substrate; first source/drain regions in the substrate interposed between the gate line structures and conductive isolation patterns; lower contact plugs on the first source/drain regions, wherein the lower contact plugs include conductive patterns formed in a recess region in an interlayer insulation layer over the first source/drain region, the conductive patterns spaced apart from one another in two orthogonal directions; an insulation pattern as a sidewall layer over the conductive patterns; and a variable-resistance structure over the lower contact plugs, wherein the conductive patterns have a vertical component that extends from a first source/drain structure to the variable resistance structure and a horizontal component that extends along the top of the first source/drain structure.

In exemplary embodiments in accordance with principles of inventive concepts, a semiconductor device includes, an oxidation-prevention layer interposed between an insulation pattern and the conductive patterns.

In exemplary embodiments in accordance with principles of inventive concepts, a semiconductor device includes a variable-resistance structure that is a Magnetic Tunnel Junction (MTJ) structure.

In exemplary embodiments in accordance with principles of inventive concepts, a semiconductor device includes a variable-resistance structure that is a phase change memory structure.

In exemplary embodiments in accordance with principles of inventive concepts, lower contact plugs face one another with mirror symmetry about a plane bisecting a conductive isolation pattern, the plane substantially perpendicular to a plane defined by the bottom surface of the substrate.

In exemplary embodiments in accordance with principles of inventive concepts, a semiconductor device includes second source/drain regions in the substrate between the gate line structures; and source line patterns connected to the second source/drain regions.

### BRIEF DESCRIPTION OF THE DRAWINGS

Exemplary embodiments in accordance with principles of inventive concepts will be more clearly understood from the following brief description taken in conjunction with the accompanying drawings. The accompanying drawings represent non-limiting, example embodiments as described herein.

FIG. 1 is a plan view illustrating semiconductor devices according to exemplary embodiments in accordance with principles of inventive concepts;

FIGS. 2A through 14B are sectional views illustrating a method of fabricating of a semiconductor device according to exemplary embodiments in accordance with principles of inventive concepts, and more particularly, FIGS. 2A through 14A are sectional views taken along lines A-A′ and B-B′ of FIG. 1, and FIGS. 2B through 14B are sectional views taken along lines C-C′ and D-D′ of FIG. 1;

FIGS. 15 and 16 shows semiconductor devices according to modifications of exemplary embodiments in accordance with principles of inventive concepts, and are sectional views enlarging a portion of FIG. 14A;

FIG. 17 is a schematic block diagram illustrating an example of electronic systems including a semiconductor device according to exemplary embodiments in accordance with principles of inventive concepts; and

FIG. 18 is a schematic block diagram illustrating an example of memory cards including the semiconductor devices according to the exemplary embodiments in accordance with principles of inventive concepts.

It should be noted that these figures are intended to illustrate the general characteristics of methods, structure and/or materials utilized in certain exemplary embodiments in accordance with principles of inventive concepts and to supplement the written description provided below. These drawings are not, however, to scale and may not precisely reflect the precise structural or performance characteristics of any given embodiment, and should not be interpreted as defining or limiting the range of values or properties encompassed by exemplary embodiments in accordance with principles of inventive concepts. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, an exemplary embodiment may be described with sectional views as ideal exemplary views of the inventive concept. Accordingly, shapes of the exemplary views may be modified according to manufacturing techniques and/or allowable errors. Therefore, exemplary embodiments of inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments in accordance with principles of inventive concepts explained and illustrated herein include their complementary counterparts. The same reference numerals or the same reference designators denote the same elements throughout the specification. Moreover, exemplary embodiments in accordance with principles of inventive concepts may be described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Example exemplary embodiments in accordance with principles of inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region foimed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

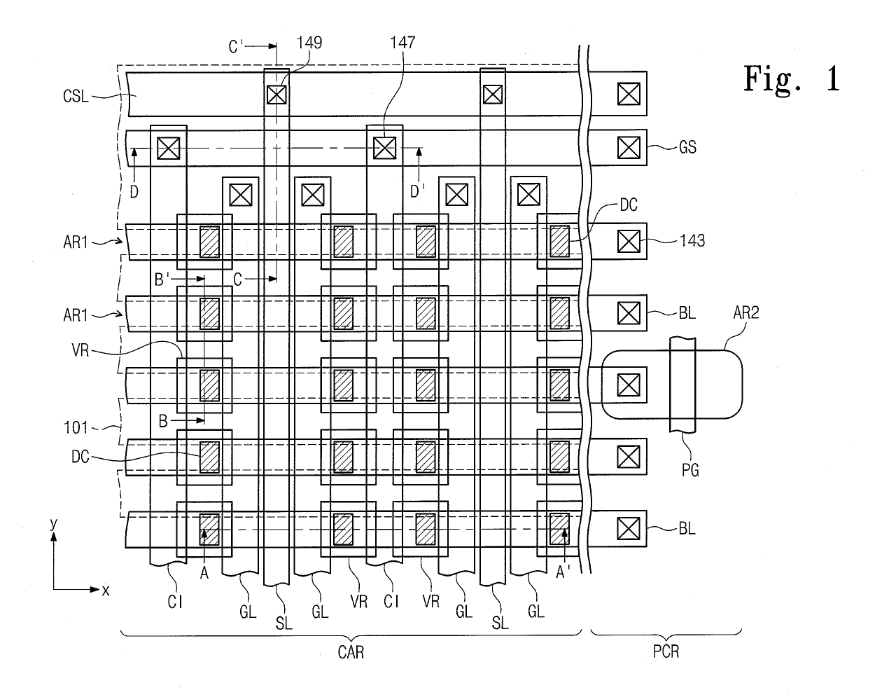

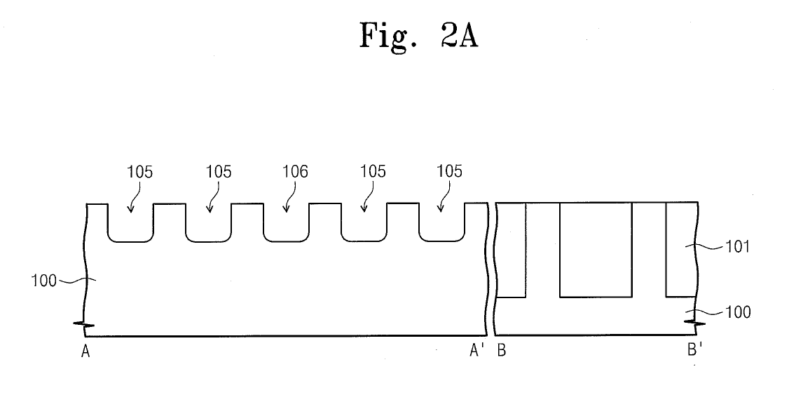

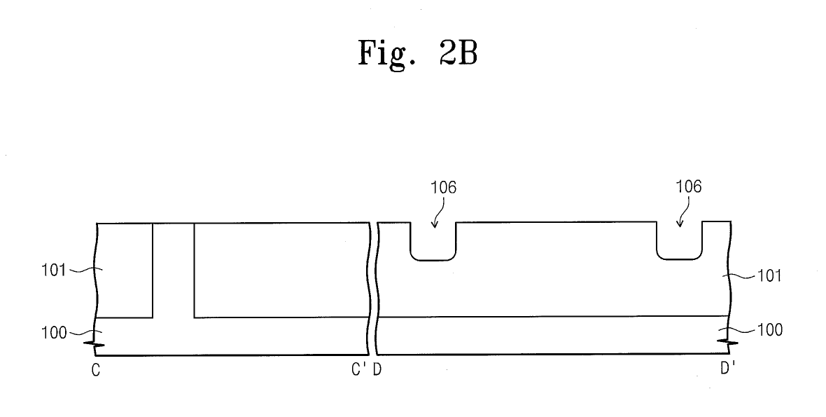

FIG. 1 is a plan view illustrating semiconductor devices according to example exemplary embodiments in accordance with principles of inventive concepts. FIGS. 2A through 14B are sectional views illustrating a method of fabricating of a semiconductor device according to exemplary embodiments in accordance with principles of inventive concepts. For example, FIGS. 2A through 14A are sectional views taken along lines A-A′ and B-B′ of FIG. 1, and FIGS. 2B through 14B are sectional views taken along lines C-C′ and D-D′ of FIG. 1.

In exemplary embodiments in accordance with principles of inventive concepts depicted in FIG. 1, FIG. 2A and FIG. 2B, device isolation layer 101 may be formed in substrate 100 to define first active region AR1 in cell array region CAR and second active region AR2 in peripheral circuit region PCR. First active region AR1 and device isolation layer 101 may be formed to have a line shape extending along x direction. Device isolation layer 101 may be formed using a trench isolation technique, for example Device isolation layer 101 may be formed of borosilicate glass (BSG), phosphosilicate glass (PSG), boro-phosphosilicate glass (BPSG), tetra-ethyl-ortho-silicate (TEOS), undoped silicate glass (USG), high density plasma (HDP) materials or spin-on-glass (SOG) materials, for example. In exemplary embodiments in accordance with principles of inventive concepts, substrate 100 may include a doped region that is lightly doped with p-type impurities.

Trenches extending along y direction may be formed in cell array region CAR. The trenches may include first trenches 105 and second trenches 106. First trench 105 may correspond to a region for disposing gate line structures to be described in the discussions related to upcoming figures, and second trenches 106 may correspond to a region for disposing conductive isolation patterns to be described in the discussions related to upcoming figures. In some exemplary embodiments, first and second trenches 105 and 106 may be formed to have substantially the same depth and width. In other exemplary embodiments, first and second trenches 105 and 106 may be formed to have different depths or different widths from each other. Hereinafter, for the sake of simplicity, the description that follows will refer to an example of an exemplary embodiment in which first and second trenches 105 and 106 are formed using the same etching process and having the same width and depth. For example, second trenches 106 may have y-directional lengths greater than first trenches 105. First and second trenches 105 and 106 may be patterned using a hard mask pattern or a photoresist pattern, and the hard mask pattern or the photoresist pattern may be removed after the formation of first and second trenches 105 and 106.

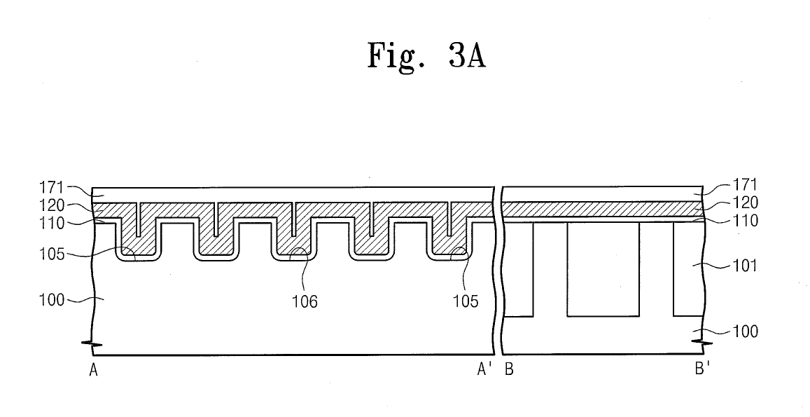

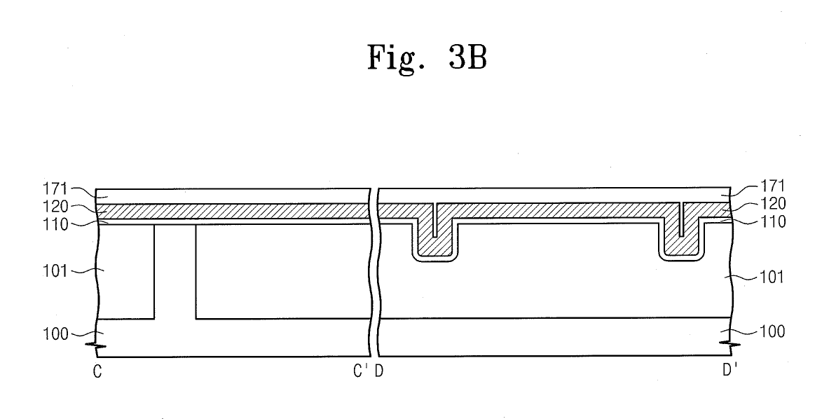

In exemplary embodiments in accordance with principles of inventive concepts depicted in FIGS. 1, 3A and 3B, a first insulating layer 110, a first conductive layer 120, and a gap-filling layer 171 may be sequentially formed on substrate 100 provided with first and second trenches 105 and 106. In exemplary embodiments, first insulating layer 110 and first conductive layer 120 may be formed to cover conformally inner surfaces of first and second trenches 105 and 106, and gap-filling layer 171 may be formed to fill the remaining spaces of first and second trenches 105 and 106. First insulating layer 110 may include at least one of silicon oxide, silicon nitride, or silicon oxynitride, for example. First conductive layer 120 may include at least one of doped semiconductor, conductive metal nitrides, metals, or metal-semiconductor compounds, for example. Gap-filling layer 171 may include at least one of silicon oxide, silicon nitride, or silicon oxynitride. First insulating layer 110, first conductive layer 120 and gap-filling layer 171 may be formed using at least one of chemical vapor deposition (CVD), physical vapor deposition (PVD), or atomic layer deposition (ALD).

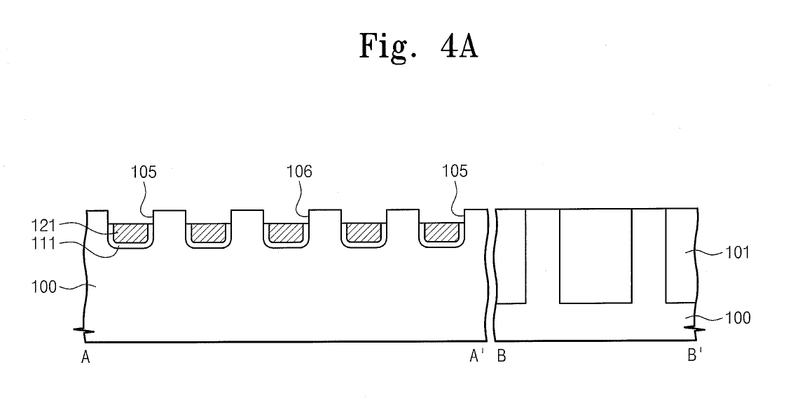

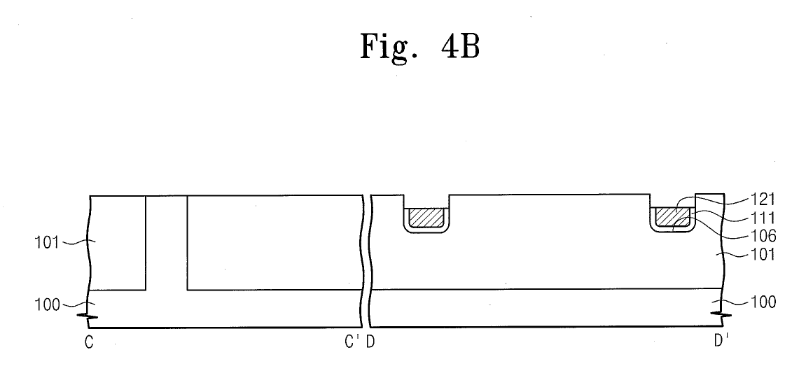

In exemplary embodiments in accordance with principles of inventive concepts depicted in FIGS. 1, 4A and 4B, first insulating layer 110, gap-filling layer 171 and first conductive layer 120 may be etched and confined in first and second trenches 105 and 106, thereby exposing a top surface of substrate 100. As the result of the etching process, first conductive layer 120 may be separated into a plurality of first conductive lines 121 and first insulating layer 110 may be separated into a plurality of first insulating patterns 111. In exemplary embodiments, before the etching process, a planarization process may be performed, such that gap-filling layer 171 may have a top surface coplanar with first conductive layer 120. Such an etching process may be performed using an etch recipe that is selected to etch first conductive layer 120 and gap-filling layer 171 with substantially the same etching rate. Due to the presence of gap-filling layer 171, it is possible to prevent first conductive lines 121 in first and second trenches 105 and 106 from being damaged during etching, for example. In exemplary embodiments, the etching process may be performed to expose top portions of first and second trenches 105 and 106, and as a result, a top surface of first conductive lines 121 may be lower than that of substrate 100. In exemplary embodiments, unlike the drawings, gap-fill layer 171 may not be completely removed, thereby leaving a portion remaining in trenches 105 and 106.

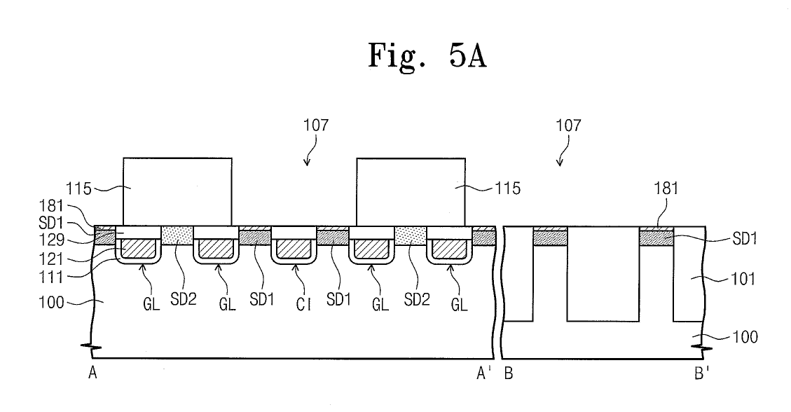

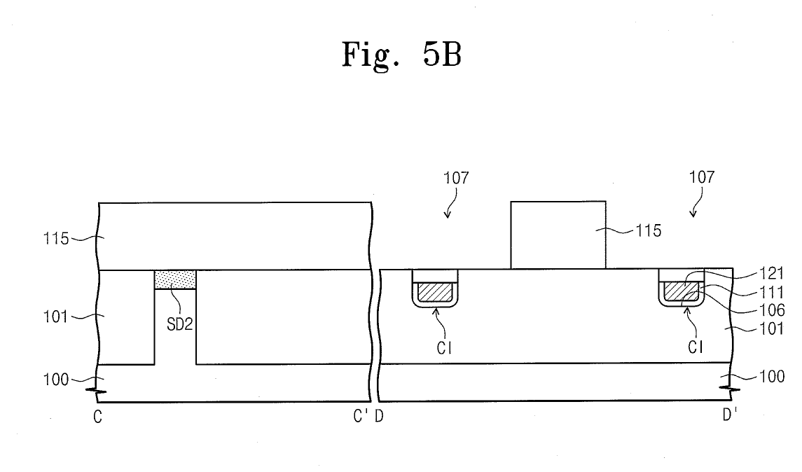

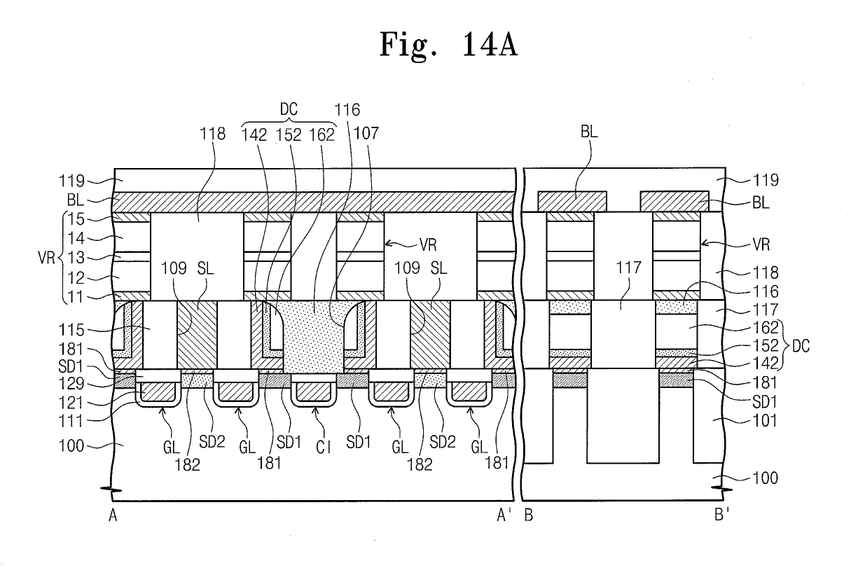

In exemplary embodiments in accordance with principles of inventive concepts depicted in FIGS. 1, 5A and 5B, first capping patterns 129 may be formed to fill the upper portions of first and second trenches 105 and 106. The formation of first capping patterns 129 may include forming an insulating layer (not shown) to fill the unoccupied recess regions formed in the upper portions of first and second trenches 105 and 106, and then performing a planarization process to expose the top surface of substrate 100. First capping patterns 129 may include at least one of silicon nitride, silicon oxide, or silicon oxynitride, for example. As the result of the formation of first capping patterns 129, gate line structures GL may be formed in first trenches 105 and conductive isolation patterns CI may be formed in second trenches 106. In exemplary embodiments, a pair of gate line structures GL may be formed between adjacent ones of conductive isolation patterns CI. Dispositions and configurations of conductive isolation patterns CI and gate line structures GL will be described in more detail in the discussion related to FIG. 14A and FIG. 14B.

In exemplary embodiments in accordance with principles of inventive concepts first and second source/drain regions SD1 and SD2 may be formed on substrate 100. First source/drain regions SD1 may be formed in substrate 100 between gate line structures GL and conductive isolation patterns CI, and second source/drain regions SD2 may be formed between gate line structures GL. First and second source/drain regions SD1 and SD2 may be formed by injecting impurities having a conductivity type different from substrate 100 into substrate 100. In exemplary embodiments, first and second source/drain regions SD1 and SD2 may be formed at the same time using the same process. Alternatively, first and second source/drain regions SD1 and SD2 may be formed by different ion implantation processes, thereby allowing for doping concentrations or doping depths different from each other. An additional implantation process may be performed to form one of first and second source/drain regions SD1 and SD2.

Hereinafter, for the sake of simplicity, the description that follows will refer to an exemplary embodiment in which source/drain regions SD1 and SD2 are formed at the same time, but embodiments in accordance with principles of inventive concepts are not limited thereto. Each of the source/drain regions SD1 and SD2 may be separated from each other by device isolation layer 101 extending along the x direction and conductive isolation patterns CI and gate line structures GL extending along the y direction, thereby forming a matrix-shaped configuration.

A first interlayered insulating layer 115 may be formed on the resultant structure provided with conductive isolation patterns CI and gate line structures GL. First interlayered insulating layer 115 may be a silicon oxide layer or silicon oxynitride layer. First interlayered insulating layer 115 may be patterned to form first recess regions 107, exposing first source/drain regions SD1. First recess regions 107 may extend along the y-direction, and each of first recess regions 107 may expose a pair of first source/drain regions SD1 adjacent to each other along the x direction and conductive isolation patterns CI between pair(s) of first source/drain regions SD1.

First metal-metal silicide layer 181 may be formed on first source/drain regions SD1 exposed by first recess regions 107. In exemplary embodiments in accordance with principles of inventive concepts, the formation of first metal-metal silicide layer 181 may include depositing a metal material on substrate 100 exposed by first recess regions 107, and then performing a thermal treatment process.

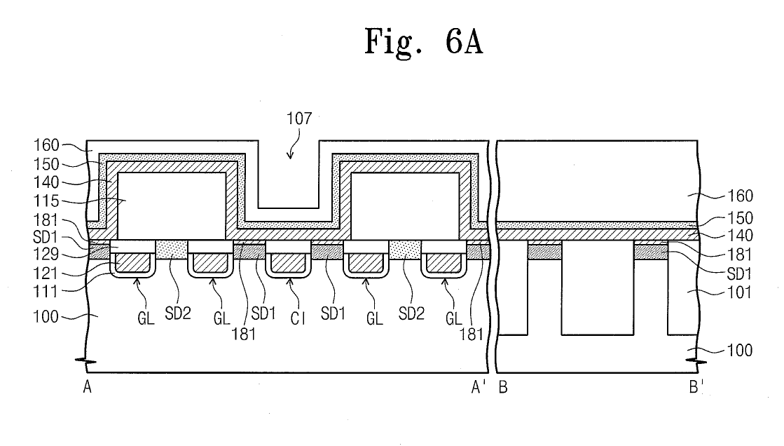

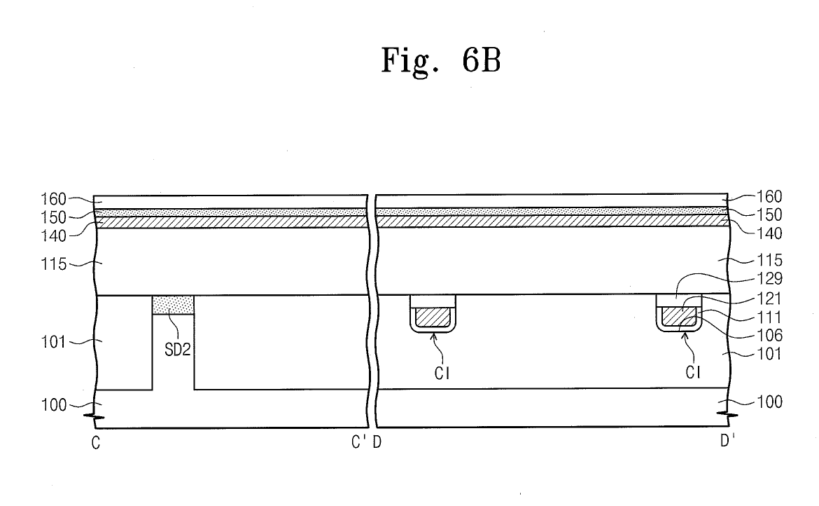

In exemplary embodiments in accordance with principles of inventive concepts depicted in FIG. 1, FIG. 6A and FIG. 6B, a second conductive layer 140 may be formed on the resultant structure provided with first recess regions 107. Second conductive layer 140 may be formed of a material including at least one of metal, conductive metal nitride, or doped silicon, for example. Second conductive layer 140 may be formed to substantially conformally cover the resultant structure provided with first interlayered insulating layer 115. A second insulating layer 160 may be formed on second conductive layer 140. Second insulating layer 160 may include at least one of a silicon oxide layer or a silicon oxynitride layer. In accordance with principles of inventive concepts, oxidation-preventing layer 150 may be formed between second conductive layer 140 and second insulating layer 160. Oxidation-preventing layer 150 may be formed between second conductive layer 140 and second insulating layer 160 to prevent second conductive layer 140 from being oxidized. Oxidation-preventing layer 150 may include a silicon nitride layer. Second conductive layer 140, oxidation-preventing layer 150, and second insulating layer 160 may be formed to incompletely fill first recess region 107.

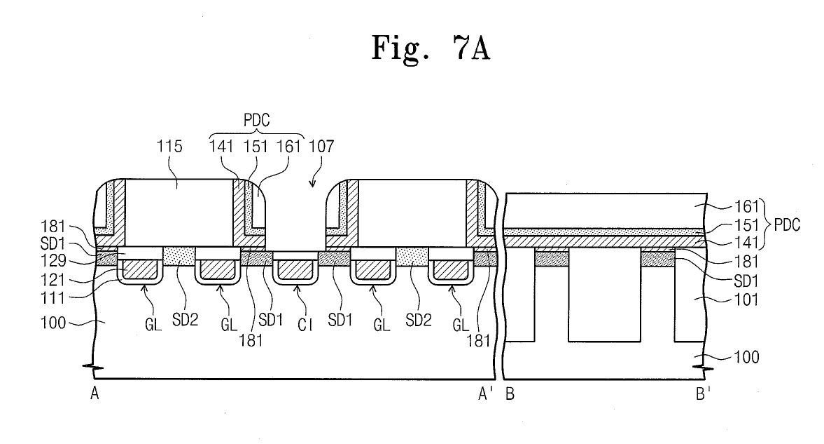

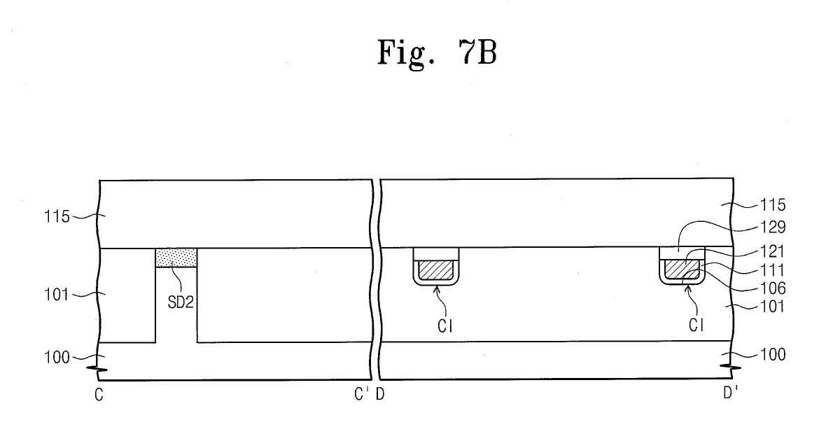

In exemplary embodiments in accordance with principles of inventive concepts depicted in FIG. 1, FIG. 7A and FIG. 7B, second conductive layer 140 may be patterned to form preliminary second conductive patterns 141 separated from each other along the x direction. The patterning of second conductive layer 140 may include a spacer forming step. For example, during the patterning of second conductive layer 140, oxidation-preventing layer 150 and second insulating layer 160 may be patterned using a dry etching process and form preliminary oxidation-preventing patterns 151 and preliminary second insulating patterns 161, which are shaped like a spacer. From a plan view, preliminary oxidation-preventing patterns 151 and preliminary second insulating patterns 161 may be formed to have a line shape extending along the y direction. Second conductive layer 140 may be separated into preliminary second conductive patterns 141 by a patterning process using preliminary oxidation-preventing patterns 151 and preliminary second insulating patterns 161 as an etch mask. In exemplary embodiments in accordance with principles of inventive concepts, upper portions of conductive isolation patterns CI may be etched during the formation of preliminary second conductive patterns 141. For example, top surfaces of conductive isolation patterns CI exposed by first recess regions 107 may be lower than those of gate line structures GL. As a result of the patterning process, preliminary lower contact plugs PDC may be formed to include: preliminary second conductive patterns 141, preliminary oxidation-preventing patterns 151, and preliminary second insulating patterns 161.

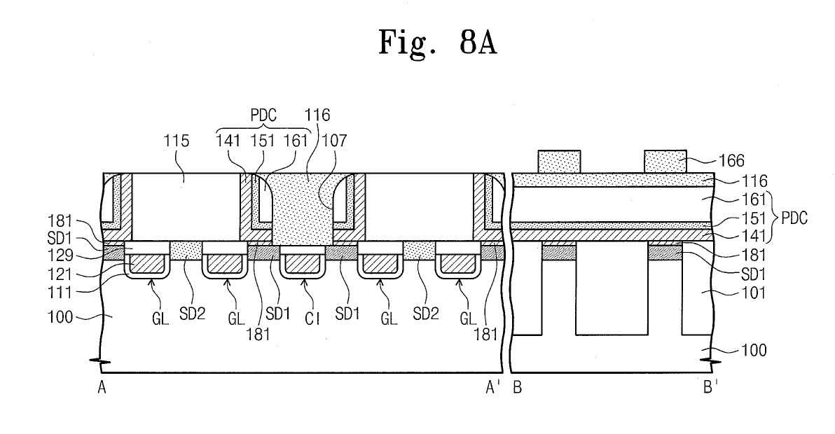

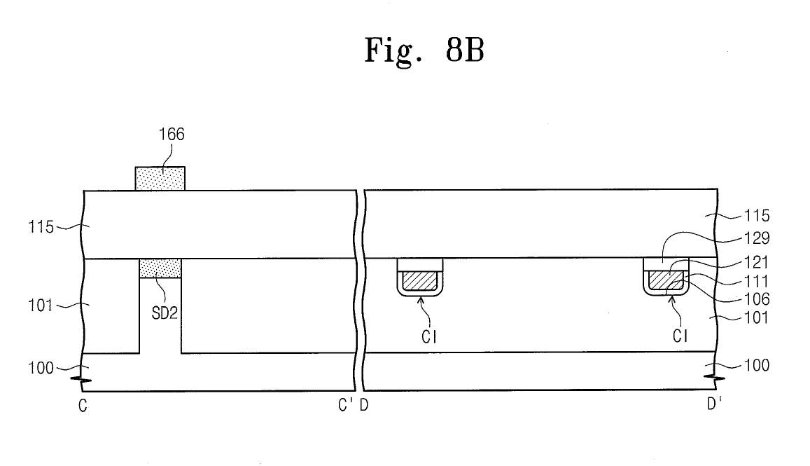

In exemplary embodiments in accordance with principles of inventive concepts depicted in FIG. 1, FIG. 8A and FIG. 8B, a third insulating layer 116 may be formed to fill first recess regions 107. Third insulating layer 116 may be confined within first recess regions 107 by a planarization process, for example. Third insulating layer 116 may include at least one of a silicon nitride layer, a silicon oxide layer, and a silicon oxynitride layer.

First mask patterns 166 may be formed on preliminary lower contact plugs PDC. First mask patterns 166 may be formed to have a line shape extending along the x direction. In exemplary embodiments in accordance with principles of inventive concepts, first mask patterns 166 may extend in the x direction along with first source/drain regions SD1 disposed along the x direction. In exemplary embodiments in accordance with principles of inventive concepts, first mask patterns 166 may be a hard mask pattern including a polysilicon layer.

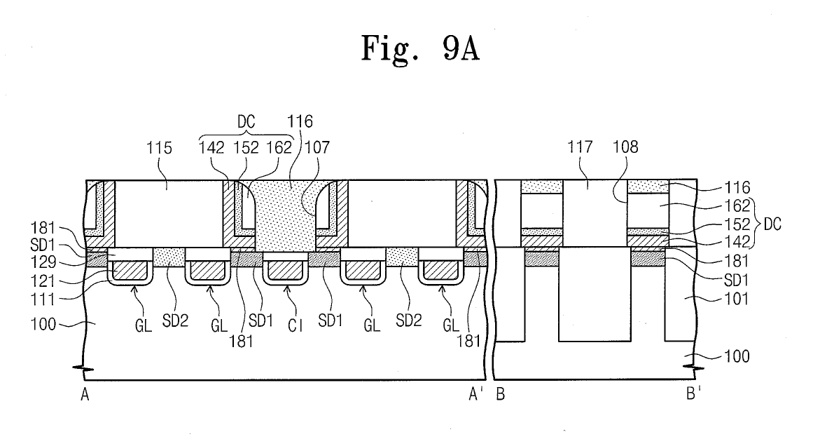

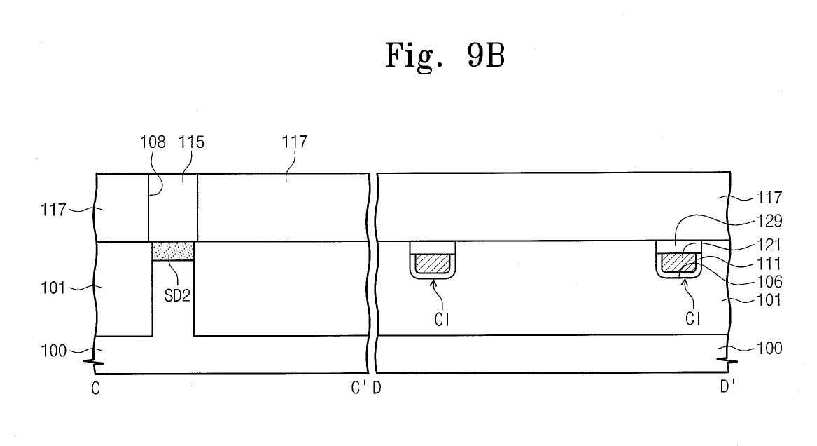

Referring to exemplary embodiments in accordance with principles of inventive concepts depicted in FIG. 1, FIG. 9A and FIG. 9B, preliminary lower contact plugs PDC may be patterned using first mask patterns 166 as an etch mask to form lower contact plugs DC. As a result of the patterning process, preliminary second conductive patterns 141, preliminary oxidation-preventing patterns 151, and preliminary second insulating patterns 161 may become second conductive patterns 142, oxidation-preventing patterns 151, and second insulating patterns 162, respectively. Lower contact plugs DC may be disposed on first source/drain regions SD1, respectively, and may be separated from each other. Y-directional widths of lower contact plugs DC may be greater than those of first source/drain regions SD1. As a result of the patterning process, second recess regions 108 may be formed to extend between lower contact plugs DC adjacent to each other in the y direction. First mask patterns 166 may be removed after the patterning process. A fourth insulating layer 117 may be formed to fill second recess regions 108. Fourth insulating layer 117 may include at least one of a silicon oxide layer, a silicon nitride layer or a silicon oxynitride layer, for example.

A method of forming lower contact plugs DC in accordance with principles of inventive concepts can have technical advantages in achieving a process margin for fabricating a highly integrated semiconductor device.

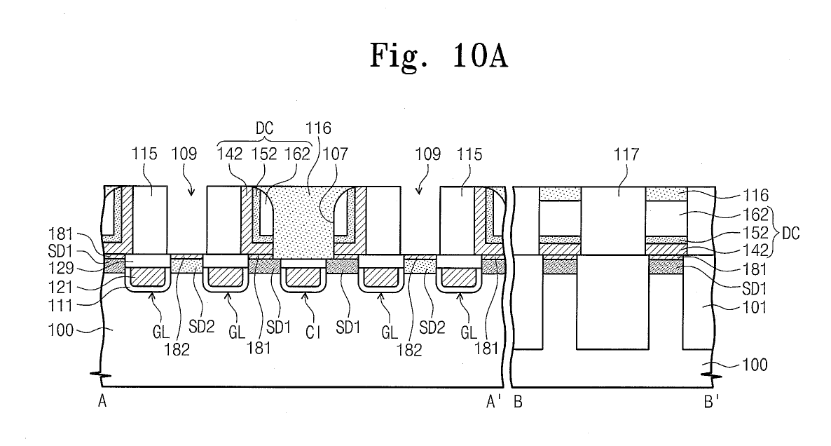

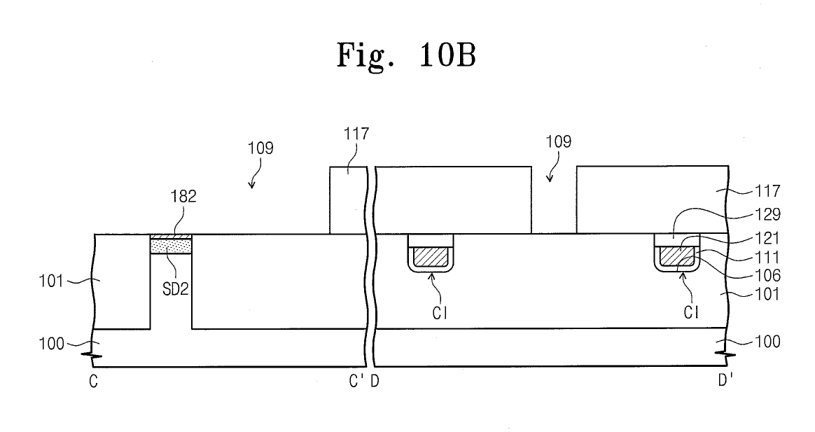

Referring to exemplary embodiments in accordance with principles of inventive concepts depicted in FIG. 1, FIG. 10A and FIG. 10B, third recess regions 109 may be formed thorough first interlayered insulating layer 115 to extend along the y direction. Third recess regions 109 may be formed to expose second source/drain regions SD2. A second metal-metal silicide layer 182 may be formed on second source/drain regions SD2 exposed by third recess regions 109. For example, the formation of second metal-metal silicide layer 182 may include depositing a metal material on substrate 100 exposed by third recess regions 109, and then performing a thermal treatment on the resultant structure.

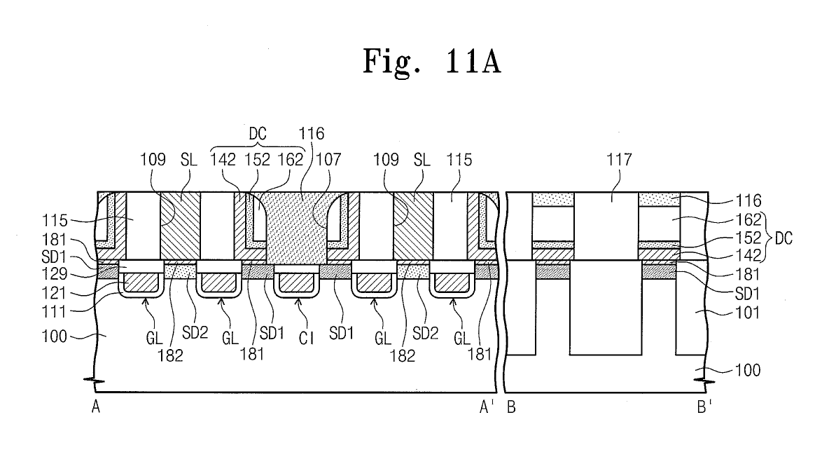

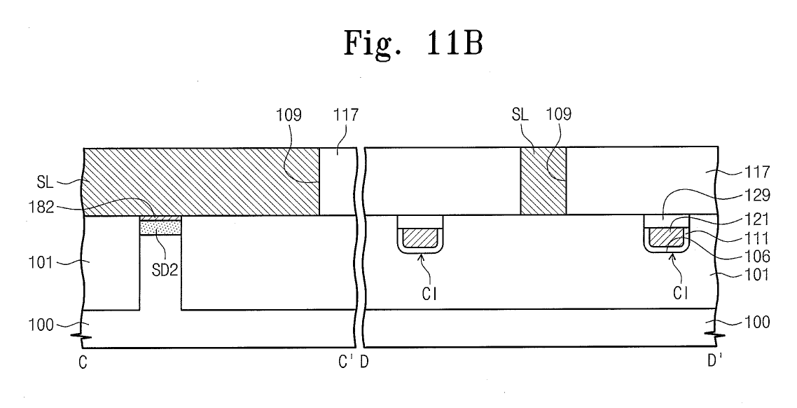

Referring to exemplary embodiments in accordance with principles of inventive concepts depicted in FIG. 1, FIG. 11A and FIG. 11B, source line patterns SL electrically connected to second source/drain regions SD2 may be formed in third recess regions 109. Source line patterns SL may extend along gate line structures GL. Source line patterns SL may be formed in third recess regions 109 by forming a conductive layer to fill third recess regions 109 and then performing a planarization process to expose first interlayered insulating layer 115. Source line patterns SL may be formed of at least one of metals, conductive metal nitrides, metal-semiconductor compounds, or doped semiconductor materials. Source line patterns SL may be formed after the formation of lower contact plugs DC.

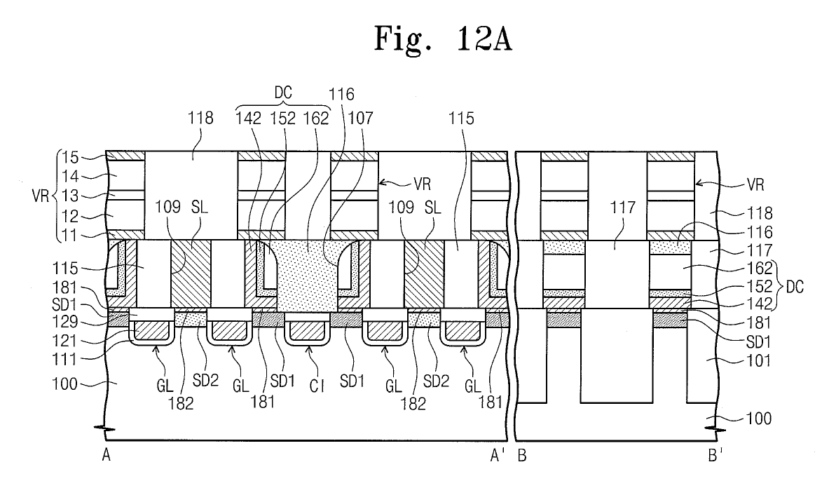

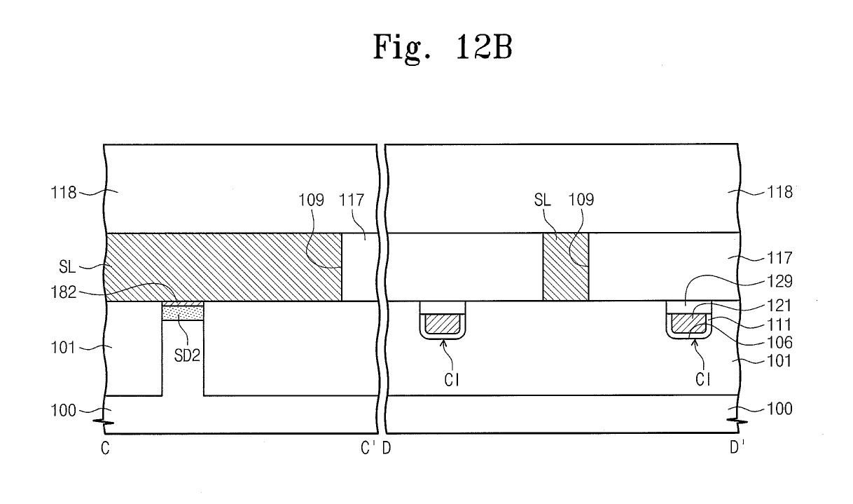

Referring to exemplary embodiments in accordance with principles of inventive concepts depicted in FIGS. 1, 12A and 12B, variable resistance structures VR may be formed on first source/drain regions SD1. Variable resistance structures VR may be electrically connected to first source/drain regions SD1 via lower contact plugs DC, respectively. In an exemplary embodiments in accordance with principles of inventive concepts applied to the fabrication of a magnetic memory device, each of variable resistance structures VR may be formed to include an Magnetic Tunnel Junction, i.e., MTJ. For example, the formation of variable resistance structures VR may include sequentially forming a first electrode 11, a reference magnetic layer 12, a tunnel barrier layer 13, a free layer 14, and a second electrode 15 on lower contact plugs DC, and patterning the resultant structure to form variable resistance structures VR disposed on lower contact plugs DC, respectively. The patterning process may include a plurality of etching steps. For example, second electrode 15 may be used as a mask for patterning layers disposed thereunder (i.e., free layer 14, tunnel barrier layer 13, and reference magnetic layer 12). After the formation of variable resistance structures VR, a second interlayer dielectric 118 may be formed to fill a space between variable resistance structures VR. Variable resistance structures VR will be described in more detail with reference to FIG. 14A and FIG. 14B.

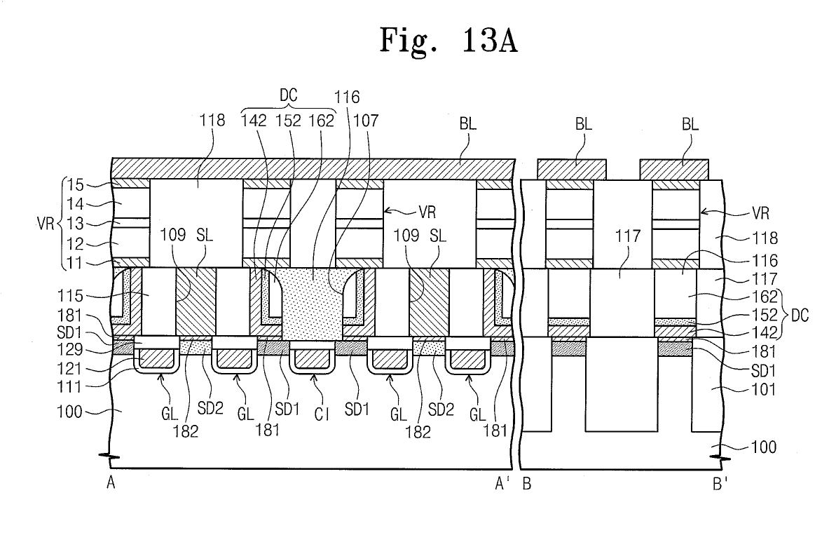

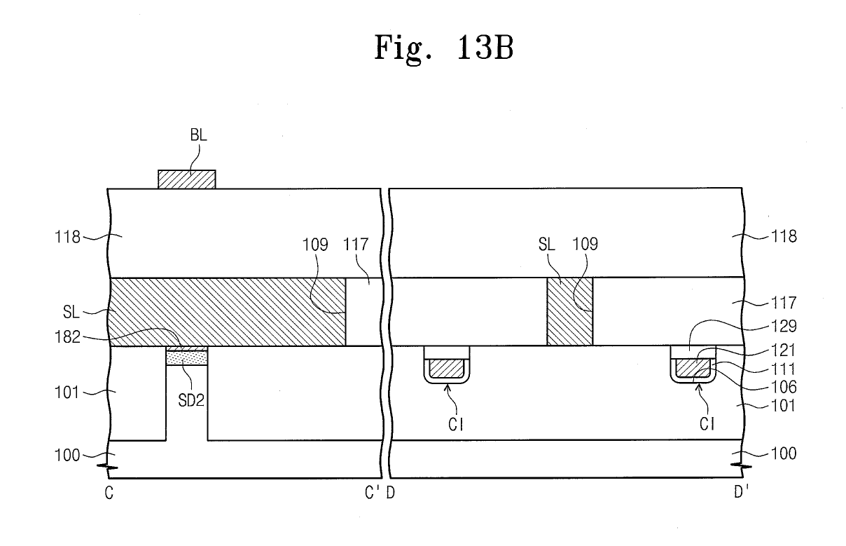

Referring to exemplary embodiments in accordance with principles of inventive concepts depicted in FIG. 1, FIG. 13A and FIG. 13B, bit lines BL may be formed to cross gate line structures GL and connect variable resistance structures VR with each other. In some embodiments, bit lines BL may be formed to be in contact with second electrodes 15. For example, bit lines BL may extend toward peripheral circuit region PCR and be electrically connected to peripheral transistors via peripheral contact plugs 143. Peripheral transistor may include a peripheral gate electrode PG.

Referring to exemplary embodiments in accordance with principles of inventive concepts depicted in FIG. 1, FIG. 14A and FIG. 14B, first contact plugs 147 and second contact plugs 149 may be formed to penetrate at least one of insulating layers 117, 118, and 119. First contact plugs 147 may penetrate first capping patterns 129 to be in contact with first conductive lines 121 constituting conductive isolation patterns CI. Second contact plugs 149 may be in contact with source line patterns SL. In the figures, each of the first and second contact plugs 147 and 149 are depicted as a single pattern, but each of first and second contact plugs 147 and 149 may be provided as a plurality of patterns in insulating layers 117, 118, and 119.

A conductive connection pattern GS may be formed to connect conductive isolation patterns CI with each other. Conductive connection pattern GS may be formed on third interlayered insulating layer 119 covering bit lines BL. Conductive connection pattern GS may be electrically connected to conductive isolation patterns CI via first contact plugs 147.

A source connection line CSL may be formed to connect source line patterns SL with each other. Source connection line CSL may be formed on third interlayered insulating layer 119 covering bit lines BL. Source connection line CSL may be electrically connected to source line patterns SL via second contact plugs 149.

Conductive connection pattern GS and source connection line CSL may be formed using the same process. Alternatively, conductive connection pattern GS and source connection line CSL may be independently formed using different processes. For example, conductive connection pattern GS may be spaced apart from source connection line CSL by an additional interlayered insulating layer.

According to exemplary embodiments in accordance with principles of inventive concepts, lower contact plugs suitable for a high density memory device can be formed through an advantageous process. In addition, a process of forming gate line structures GL may be at least partially used for advantageously forming conductive isolation patterns CI, which may serve as an isolation structure between gate line structures GL.

Hereinafter, a variable resistance memory device according to exemplary embodiments in accordance with principles of inventive concepts will be again described with reference to FIG. 1, FIG. 14A and FIG. 14B.

Substrate 100 including cell array region CAR and peripheral circuit region PCR may be provided. Substrate 100 may be one of a semiconductor layer, an insulating layer, a semiconductor or conductive layer covered with an insulating layer. For example, substrate 100 may be a silicon wafer. In exemplary embodiments in accordance with principles of inventive concepts, substrate 100 may include a region lightly doped with p-type impurities. A device isolation layer 101 may be disposed in substrate 100 to define first active region AR1 in cell array region CAR and second active region AR2 in peripheral circuit region PCR. first active region AR1 may be shaped like a line parallel to a specific direction (for example, x direction). A peripheral gate electrode structure PG may be provided on peripheral circuit region PCR.

Gate line structures GL may include at least a portion inserted into substrate 100. For example, substrate 100 may be formed to have first trenches 105 and gate line structures GL may be disposed in first trenches 105. Gate line structures GL may extend along a direction (e.g., y direction) crossing device isolation layer 101. Each of gate line structures GL may include first conductive line 121 provided in first trench 105, first insulating pattern 111 surrounding side and bottom surfaces of first conductive line 121, and first capping pattern 129 provided on first conductive line 121 to fill remaining space of first trench 105. Each of first insulating patterns 111 may serve as a gate insulating layer of a transistor that includes gate line structures GL. First insulating patterns 111 and first capping patterns 129 may separate, or isolate, first conductive lines 121 electrically from substrate 100.

First conductive lines 121 may include a conductive material. For example, first conductive lines 121 may include doped semiconductor, conductive metal nitrides, metals, or metal-semiconductor compounds. First insulating patterns 111 may include silicon oxide, silicon nitride, or silicon oxynitride, for example. First capping patterns 129 may include silicon nitride, silicon oxide, or silicon oxynitride, for example. In exemplary embodiments in accordance with principles of inventive concepts, gate line structures GL may serve as word lines of the variable resistance memory device.

Second source/drain regions SD2 may be provided in substrate 100 between first conductive lines 121 adjacent to each other, and source line patterns SL may be provided on second source/drain regions SD2. Due to the presence of device isolation layer 101, second source/drain regions SD2 may be separated from each other in the y direction. Source line patterns SL may connect second source/drain regions SD2 arranged along the y direction. That is, second source/drain regions SD2 spaced apart from each other in the y direction may be connected to each other by the respective one of source line patterns SL. Source line patterns SL may be formed in or through first interlayer dielectric 115 covering second source/drain regions SD2 and extend along the y direction parallel to gate line structures GL. For example, each of source line patterns SL may serve as a common source line. Additionally, second source/drain regions SD2 may be electrically connected to source line patterns SL, in a manner that may allow each of second source/drain regions SD2 may serve as a common source region of the transistors disposed adjacent thereto. Second metal-silicide layers 182 may be provided between source line patterns SL and second source/drain regions SD2. The presence of second metal-silicide layer 182 may contribute to a reduction of contact resistance between source line patterns SL and second source/drain regions SD2, for example.

Second source/drain regions SD2 may be a heavily doped region having a different conductivity type from that of substrate 100. For example, in an embodiment where substrate 100 is p-type, second source/drain regions SD2 may be n-type. Source line patterns SL may include metals, conductive metal nitrides, or metal-semiconductor compounds. For example, source line patterns SL may include at least one of tungsten, titanium or tantalum. Source line patterns SL may further include a doped semiconductor layer.

Source line patterns SL may be electrically connected with each other. In exemplary embodiments in accordance with principles of inventive concepts, source connecting line CSL may be provided to electrically connect source line patterns SL with each other. Source connecting line CSL may extend along a direction crossing source line patterns SL. In exemplary embodiments in accordance with principles of inventive concepts, source connection line CSL may be electrically connected to source line patterns SL via second contact plugs 149 penetrating insulating layers 118 and 119.

Source connecting line CSL may be disposed at a side of source line patterns SL as shown in FIG. 1, but exemplary embodiments in accordance with principles of inventive concepts are not limited thereto. For example, source connecting line CSL may be configured to have a structure capable of connecting source line patterns SL electrically with each other. In exemplary embodiments in accordance with principles of inventive concepts, source connecting line CSL may be disposed at both sides of source line patterns SL. In other exemplary embodiments, source connecting line CSL may be disposed around cell array region CAR to have a closed loop shape.

Conductive isolation patterns CI may be provided with gate line structures GL interposed therebetween and be spaced apart from source line patterns SL. That is, each of source line patterns SL may extend between adjacent pairs of conductive isolation patterns CI, respectively, and gate line structures GL may be extend between source line patterns SL and conductive isolation patterns CI. Conductive isolation patterns CI may be buried in an upper portion of substrate 100. In exemplary embodiments in accordance with principles of inventive concepts, conductive isolation patterns CI may be provided in second trenches 106 formed in substrate 100. Second trenches 106 may be formed substantially parallel to first trenches 105. In some exemplary embodiments in accordance with principles of inventive concepts, first and second trenches 105 and 106 may be formed using the same etching process. In such embodiments, second trenches 106 may be formed to have substantially same shape as first trenches 105.

Conductive isolation patterns CI may be formed to have substantially the same structure as gate line structures GL. For example, each conductive isolation pattern CI may include first conductive line 121, first insulating patterns 111 surrounding side and bottom surfaces of first conductive line 121, and first capping pattern 129 provided on first conductive line 121 to fill second trench 106, similar to gate line structures GL.

Conductive isolation patterns CI may be electrically connected with each other. In some exemplary embodiments in accordance with principles of inventive concepts, conductive connection pattern GS may be provided to electrically connect conductive isolation patterns CI with each other. Conductive isolation patterns CI may be electrically connected to conductive connection pattern GS via first contact plugs 147.

Conductive connection pattern GS may extend along a direction crossing conductive isolation patterns CI. Conductive isolation patterns CI may extend laterally to be disposed on peripheral circuit region PCR. Conductive connection pattern GS may be disposed at a side of conductive isolation patterns CI as shown in FIG. 1, but exemplary embodiments in accordance with principles of inventive concepts are not limited thereto. For example, conductive connection pattern GS may be configured to have a structure capable of connecting conductive isolation patterns CI electrically with each other. In some exemplary embodiments in accordance with principles of inventive concepts, conductive connection pattern GS may be disposed at both sides of conductive isolation patterns CI. In other exemplary embodiments in accordance with principles of inventive concepts, conductive connection pattern GS may be disposed around cell array region CAR to have a closed-loop shape. Conductive connection pattern GS and first contact plugs 147 may include metals, conductive metal nitrides, metal-semiconductor compounds, or doped semiconductors, for example.

First source/drain regions SD1 may be provided between gate line structures GL and conductive isolation patterns CI. First source/drain regions SD1 may be impurity regions that are heavily doped with impurities having a different conductivity type from that of substrate 100. First source/drain regions SD1 may be spaced apart from each other, in y-direction, by device isolation layer 101, for example. In some exemplary embodiments in accordance with principles of inventive concepts, first source/drain regions SD1 may serve as drain regions of transistors controlled by gate line structures GL. In an exemplary embodiment in which a voltage higher than a threshold voltage is applied to gate line structures GL, channels (not shown) may be formed under gate line structures GL to electrically connect first source/drain regions SD1 with second source/drain regions SD2. Such a channel may be formed along a surface of substrate 100 facing side and bottom surfaces of each gate line structure GL, and as a result, a length of the channel may be elongated, compared with an embodiment in which the gate structure is formed on a substrate 100. Such an elongation in channel length may relieve a short channel effect that may otherwise occur in a semiconductor device with an increased integration density.

Lower contact plugs DC may be provided on first source/drain regions SD1, respectively. Lower contact plugs DC, which may be adjacent to each other with conductive isolation patterns CI interposed therebetween may be disposed to have mirror symmetry. Lower contact plugs DC may include second conductive patterns 142, oxidation-preventing patterns 152, and second insulating patterns 162 sequentially stacked on the substrate. For example, second conductive patterns 142 may be formed to have an ‘L’-shaped vertical section, and oxidation-preventing patterns 152 and second insulating patterns 162 having a spacer shape may be formed on sidewalls of second conductive patterns 142.

Second conductive patterns 142 may include at least one of metals, conductive metal nitrides, or doped silicon. For example, second insulating patterns 162 may include at least one layer of a silicon oxide layer, and oxidation-preventing patterns 152 may include a silicon nitride layer.

Bit lines BL may be provided to cross gate line structures GL. Bit lines BL may extend toward peripheral circuit region PCR and may be electrically connected to a peripheral transistor including peripheral gate electrode PG via peripheral contact plugs 143.

Variable resistance structures VR may be provided between lower contact plugs DC and bit lines BL, respectively. Variable resistance structures VR may be provided in second interlayer dielectric 118. The value of data stored in variable-resistance structures VR may depend on, or correlate to, the value of the resistance of the structure. In some embodiments, variable resistance memory device may be a magnetic random access memory device (MRAM), in which a magnetic tunnel junction (MTJ) is used as variable resistance structure VR.

However, exemplary embodiments in accordance with principles of inventive concepts are not limited thereto. For example, a semiconductor device according to exemplary embodiments in accordance with principles of inventive concepts may be a phase changeable memory device (or PRAM), a ferroelectric memory device (or FRAM), or a resistive memory device (or RRAM). In an example of this embodiment as applied to the PRAM, variable resistance structure VR may include a phase changeable material interposed between electrodes. In an exemplary embodiment in accordance with principles of inventive concepts as applied to a FRAM, variable resistance structure VR may include a ferroelectric layer interposed between electrodes. Hereinafter, for the sake of simplicity, the description that follows will refer to an exemplary embodiment in accordance with principles of inventive concepts including the MTJ. However, exemplary embodiments in accordance with principles of inventive concepts are not limited thereto.

Each of variable resistance structures VR may include reference magnetic layer 12, tunnel barrier layer 13, and free layer 14, which may be sequentially stacked between first electrode 11 and second electrode 15. Reference magnetic layer 12 and free layer 14 may be interchangeable in terms of vertical position. In addition, each of variable resistance structures VR may be configured to include one or more reference magnetic layers and/or one or more free layers. Electric resistance of each MTJ may vary depending on whether magnetizations of reference magnetic layer 12 and free layer 14 are parallel. That is, the electric resistance of MTJ may be higher when magnetizations of reference magnetic layer 12 and free layer 14 are anti-parallel, than when they are parallel. This difference in electric resistance may be used to write and/or read out data of a magnetic tunnel junction memory device.

Each of first and second electrodes 11 and 15 may include a conductive material having a low reactivity. For example, first and second electrodes 11 and 15 may be formed of conductive metal nitrides. In some embodiments, at least one of first and second electrodes 11 and 15 may include at least one material selected from a group consisting of titanium nitride, tantalum nitride, tungsten nitride, or titanium aluminum nitride.

Exemplary embodiments in accordance with principles of inventive concepts of a horizontal-type MTJ, reference magnetic layer 12 may include a pinning layer and a pinned layer. The pinning layer may include an anti-ferromagnetic material. For example, the pinning layer may include at least one material selected from a group consisting of PtMn, IrMn, MnO, MnS, MnTe, MnF₂, FeCl₂, FeO, CoCl₂, CoO, NiCl₂, NiO or Cr. In such an embodiment, a magnetization direction of the pinned layer may be fastened by the pinning layer. The pinned layer may include a ferromagnetic material. For example, the pinned layer may include at least one material selected from a group consisting of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂.

Tunnel barrier layer 13 may be formed to a thickness smaller than a spin diffusion distance. Tunnel barrier layer 13 may include a nonmagnetic material. For example, tunnel barrier layer 13 may include at least one material selected from a group consisting of magnesium oxide, titanium oxide, aluminum oxide, magnesium-zinc oxide and magnesium-boron oxide, titanium nitride or vanadium nitride.

Free layer 14 may include a material exhibiting a switchable magnetization direction. For example, a magnetization direction of free layer 14 may be changed by an internal or external electromagnetic effect. In some exemplary embodiments in accordance with principles of inventive concepts, free layer 14 may include a ferromagnetic material containing, for example, at least one of cobalt, iron or nickel. For example, free layer 14 may include at least one material selected from a group consisting of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂.

However, exemplary embodiments in accordance with principles of inventive concepts are not limited to the variable resistance memory device including horizontal-type MTJ. For example, the variable resistance memory device may include a perpendicular-type MTJ. In such an embodiment, magnetization directions of reference magnetic layer 12 and free layer 14 may be substantially parallel to a normal of tunnel barrier layer 13.

In an exemplary embodiment in accordance with principles of inventive concepts as applied to the variable resistance memory device, operations of reading a datum, writing a datum ‘1’, and writing a datum ‘0’ may be performed based on the conditions given by the following table 1. In this exemplary embodiment, the afore-described gate line structure GL may correspond to a word line WL in the table 1.

TABLE 1

| | WL (GL) | | BL | | | |
|---|---|---|---|---|---|---|
| | Sel-WL | Unsel-WL | Sel-BL | Unsel-BL | CI | SL |
| Writing of | Vg1 | GND or | Vd1 | GND or | GND or | Vsl |
| datum ‘1’ | | negative | | floating | negative | (1 V or |
| | | | | | | GND) |
| Writing of | Vg0 | GND or | Vd0 | GND or | GND or | Vsl |
| datum ‘0’ | | negative | | floating | negative | (1 V or |
| | | | | | | GND) |
| Reading | Vgr | GND or | Vr | GND or | GND or | Vsl |
| | | negative | | floating | negative | (1 V or |
| | | | | | | GND) |

From Table 1, operations of writing a datum ‘1’, writing a datum ‘0’ and reading a datum may be performed under conditions of applying voltages of Vg1, Vg0 and Vgr, respectively, to a selected word line Sel-WL. In this exemplary embodiment, voltages of Vg1, Vg0, and Vgr may be higher than a threshold voltage of a corresponding transistor and may be adjusted in consideration for a material of variable resistance structure VR, a doping concentration of source/drain regions, a thickness of a gate insulating layer, and so forth. In some exemplary embodiments in accordance with principles of inventive concepts, voltage Vg1 may be substantially equivalent to voltage Vg0, and voltage Vgr may be relatively lower than voltages Vg1 and Vg0. For example, voltages Vg1 and Vg0 may be in rage of about 0.5 to about 5V. Unselected word line Unsel-WL may be applied with a ground voltage GND or a negative voltage, during operation.

In writing and reading operations, source line patterns SL may have voltage Vsl applied to it. In some exemplary embodiments in accordance with principles of inventive concepts, voltage Vsl may be about 1V or a ground voltage GND. The operations of writing a datum ‘1’, writing a datum ‘0,’ and reading a datum may be performed under conditions of applying voltages of Vd1, Vd0 and Vr, respectively, to a selected bit line Set-BL. Voltage Vsl may be lower than voltage Vd1 and may be higher than voltage Vd0. In other exemplary embodiments in accordance with principles of inventive concepts, voltage Vd1 may be equivalent to or higher than voltage Vd0, depending on a material used for variable resistance structure VR. A ground voltage GND may be applied to an unselected bit line Unsel-BL or it may be in an electrically floating state.

In writing and reading operations, a ground voltage GND or a negative voltage may be applied to conductive isolation patterns CI. For example, substantially same voltage as that applied to unselected word line Unsel-WL may be applied to conductive isolation patterns CI. In other embodiments, a voltage less than that applied to unselected word line Usel-WL may be applied to conductive isolation patterns CI.

In an exemplary embodiment in which a ground voltage GND or a negative voltage may be applied to conductive isolation patterns CI, it is possible to prevent a potential of conductive isolation pattern CI from being boosted by a voltage applied to gate line structures GL adjacent thereto and therefore, to prevent a channel from being formed under the corresponding conductive isolation pattern CI. As will be described below, in an exemplary embodiment in accordance with principles of inventive concepts conductive isolation patterns CI may be formed by using at least a portion of a process for forming gate line structures GL. As a result, gate line structures GL can be advantageously electrically isolated. In addition, the ground or negative voltage can be simultaneously applied to a plurality of conductive isolation patterns CI using conductive connection pattern GS.

In some exemplary embodiments in accordance with principles of inventive concepts, gate line structures GL buried in substrate 100 may prevent a short channel effect from occurring. Additionally, adjacent gate line structures GL may share a source region via source line patterns SL, thereby permitting integration density for the device. In addition, conductive isolation patterns CI may be formed by at least partially using a process for forming gate line structures GL, and thus, an insulation structure between gate line structures GL can be advantageously formed.

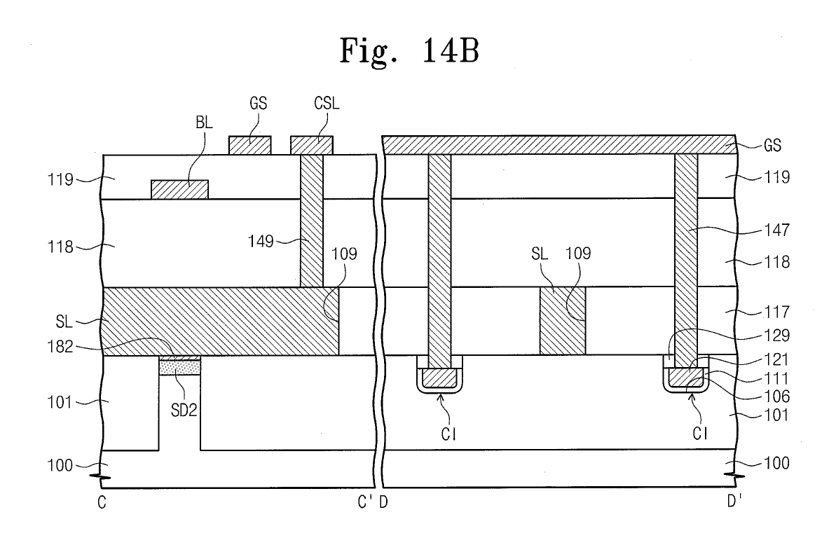

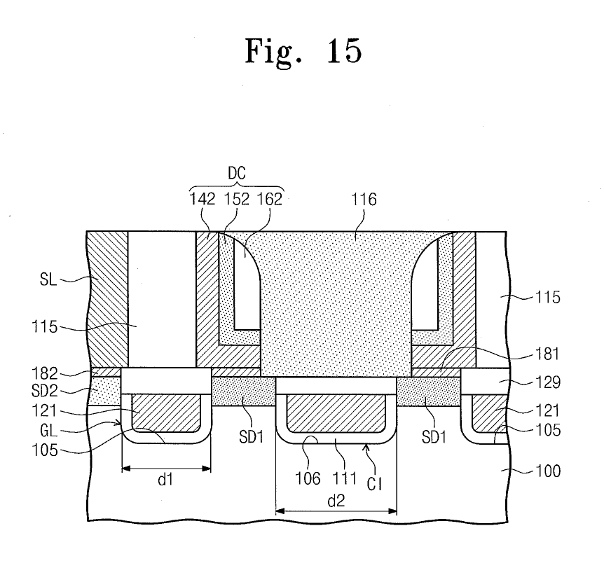

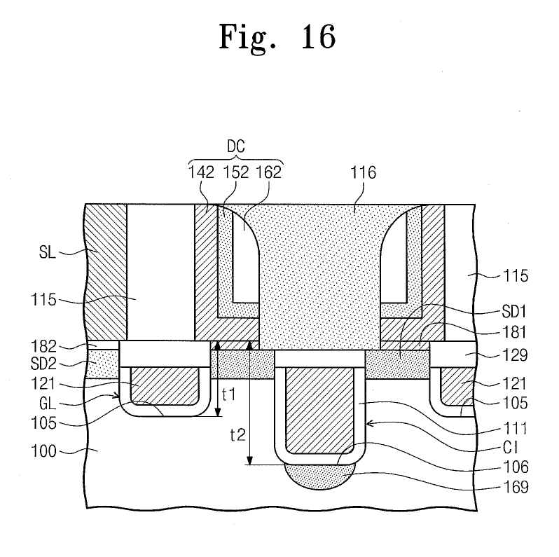

FIGS. 15 and 16 show semiconductor devices according to modifications exemplary embodiments in accordance with principles of inventive concepts, and are sectional views enlarging a portion of FIG. 14A. As shown in FIG. 15, width d2 of conductive isolation pattern CI may be greater than width d1 of gate line structure GL. In other exemplary embodiments in accordance with principles of inventive concepts, thickness t2 of conductive isolation pattern CI may be greater than thickness t1 of gate line structure GL. These modifications related to conductive isolation patterns CI may be achieved by changing shapes of first and/or second trenches 105 and/or 106. For example, the structure shown in FIG. 15 may be obtained by patterning second trenches 106 to have a width greater than a width of first trench 105. Additionally, the structure of FIG. 16, in which first trench 105 is formed to have a different depth from that of second trench 106, may be obtained by separately etching first and second trenches 105 and 106. A channel stop region 169 may be formed in substrate 100 below conductive isolation patterns CI and electrically isolate adjacent source/drain regions from each other. Channel stop region 169 may be formed by injecting impurities with the same conductivity type as substrate 100 into substrate 100 under second trenches 106. For example, the formation of the structure shown in FIG. 16 may include forming first trenches 105, forming a mask (not shown) covering first trenches 105, forming second trenches 106 in substrate 100 exposed by the mask, and performing an ion implantation process to locally form channel stop regions 169 at bottoms of second trenches 106.

Semiconductor devices in accordance with principles of inventive concepts disclosed above may be encapsulated using various and diverse packaging techniques. For example, the semiconductor devices according to the aforementioned exemplary embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique. The package in which a semiconductor device in accordance with principles of inventive concepts is mounted may also include at least one semiconductor device (e.g., a controller and/or a logic device) that controls the semiconductor device.

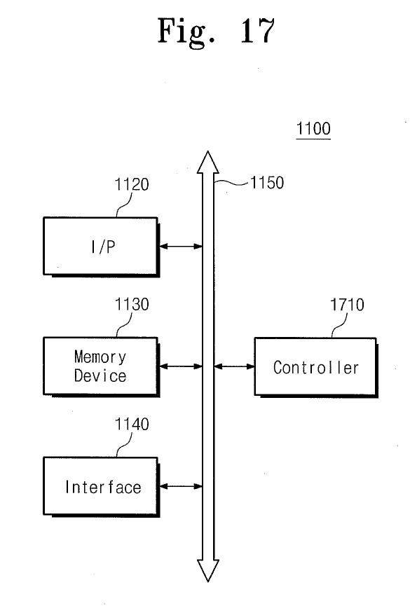

FIG. 17 is a schematic block diagram illustrating an example of electronic systems including a semiconductor device according to exemplary embodiments in accordance with principles of inventive concepts.

Referring to FIG. 17, an electronic system 1100 in accordance with principles of inventive concepts may include a controller 1110, an input/output (I/O) unit 1120, a memory device 1130, an interface unit 1140 and a data bus 1150. At least two of controller 1110, I/O unit 1120, memory device 1130 and interface unit 1140 may communicate with each other through data bus 1150. Data bus 1150 may correspond to a path through which electrical signals are transmitted.

Controller 1110 may include at least one of a microprocessor, a digital signal processor, a microcontroller or another logic device. The other logic device may have a similar function to any one of the microprocessor, the digital signal processor and the microcontroller. I/O unit 1120 may include a keypad, a keyboard or a display unit. Memory device 1130 may store data and/or commands. Memory device 1130 may include at least one of the data storing devices according to exemplary embodiments described above. Memory device 1130 may also include another type of data storing device, which are different from data storing devices described above. Interface unit 1140 may transmit electrical data to a communication network or may receive electrical data from a communication network. Interface unit 1140 may operate by wireless or cable. For example, interface unit 1140 may include an antenna for wireless communication or a transceiver for cable communication. Although not shown in the drawings, electronic system 1100 may further include a fast DRAM device and/or a fast SRAM device that acts as a cache memory for improving an operation of controller 1110.

Electronic system 1100 may be applied to a personal digital assistant (PDA), a portable computer, a web tablet, a wireless phone, a mobile phone, a digital music player, a memory card or an electronic product. The electronic product may receive or transmit information data by wireless transmission, for example.

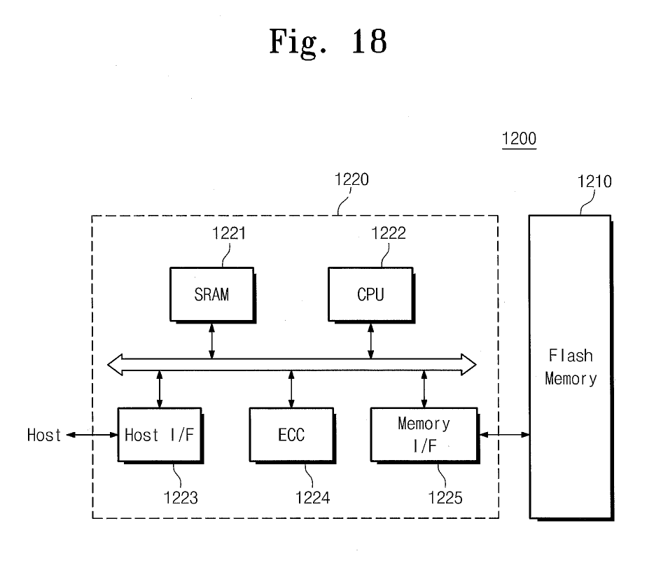

FIG. 18 is a schematic block diagram illustrating an exemplary embodiment of memory cards including the semiconductor devices according to the exemplary embodiments in accordance with principles of inventive concepts.

Referring to FIG. 18, a memory card 1200 according to an embodiment of the inventive concept may include a memory device 1210. Memory device 1210 may include at least one of the data storing devices according to the various embodiments mentioned above. In other embodiments, memory device 1210 may further include another type of data storing devices, which are different from the data storing devices according to embodiments described above. memory card 1200 may include a memory controller 1220 that controls data communication between a host and memory device 1210.

Memory controller 1220 may include a central processing unit (CPU) 1222 that controls overall operations of memory card 1200. In addition, memory controller 1220 may include an SRAM device 1221 used as an operation memory of CPU 1222. Moreover, memory controller 1220 may further include a host interface unit 1223 and a memory interface unit 1225. Host interface unit 1223 may be configured to include a data communication protocol between memory card 1200 and the host. Memory interface unit 1225 may connect memory controller 1220 to memory device 1210. Memory controller 1220 may further include an error check and correction (ECC) block 1224. ECC block 1224 may detect and correct errors of data which are read out from memory device 1210. Even though not shown in the drawings, the memory card 1200 may further include a read only memory (ROM) device that stores code data to interface with the host. Memory card 1200 may be used as a portable data storage card. Alternatively, memory card 1200 may replace hard disks of computer systems as solid state disks (SSD) of the computer systems.

According to exemplary embodiments in accordance with principles of inventive concepts, provided is a method of forming contact plugs suitable for a high density memory device. According to the method, the contact plugs can be formed through an advantageous process. In addition, a source line pattern serving as a common source line of adjacent gates is provided to improve the integration density of a semiconductor device. Conductive isolation patterns can be formed advantageously between gate line structures, in a manner that allows them to be used as structures for electrically isolating adjacent gate line structures from each other.

While exemplary embodiments in accordance with principles of inventive concepts have been particularly shown and described, it will be understood that variations in form and detail may be made therein without departing from the spirit and scope of the attached claims.

1. A method of fabricating a variable resistance memory device, comprising:
forming first source/drain regions in a substrate;
forming gate line structures and conductive isolation patterns buried in the substrate with the first source/drain regions interposed therebetween; and
forming lower contact plugs on the first source/drain regions,
wherein the forming of the lower contact plugs comprises:
forming a first interlayered insulating layer including a first recess region exposing the first source/drain regions adjacent to each other in a first direction;
forming a conductive layer in the first recess region;
patterning the conductive layer to form preliminary conductive patterns spaced apart from each other in the first direction; and
patterning the preliminary conductive patterns to form conductive patterns spaced apart from each other in a second direction substantially orthogonal to the first direction.

2. The method of claim 1, wherein the forming of the lower contact plugs further comprises forming an insulating layer on the conductive layer.

3. The method of claim 2, wherein the forming of the preliminary conductive patterns comprises a spacer forming process, in which the insulating layer is patterned using a dry etching process.

4. The method of claim 2, wherein forming the insulating layer comprises forming a multi-layered structure including an oxide layer on the conductive layer and an oxidation-preventing layer between the conductive layer and the oxide layer.

5. The method of claim 4, wherein the oxidation-preventing layer comprises a silicon nitride layer.

6. The method of claim 1, wherein the conductive isolation pattern is provided between the first source/drain regions adjacent to each other in the first direction, and
an upper portion of the conductive isolation pattern is etched during the forming of the preliminary conductive patterns.

7. The method of claim 1, wherein the lower contact plugs adjacent to each other with the conductive isolation patterns interposed therebetween are disposed to have mirror symmetry about a plane bisecting the conductive isolation patterns and substantially perpendicular to a plane formed by the bottom surface of the substrate.

8. The method of claim 1, further comprising, forming a first metal silicide between the conductive layer and the first source/drain regions.

9. The method of claim 1, further comprising,
forming second source/drain regions in the substrate between the gate line structures; and
forming source line patterns on the second source/drain regions to extend along the gate line structures.

10. The method of claim 9, wherein the source line patterns are formed in trenches provided in the first interlayered insulating layer, and
the lower contact plugs are formed before the forming of the source line patterns.

11. The method of claim 9, further comprising, forming a device isolation layer in the substrate to cross the gate line structures,
wherein the second source/drain regions are spaced apart from each other in the second direction by the device isolation layer, and
wherein the second source/drain regions separated from each other in the second direction are electrically connected to each other by the source line patterns.

12. The method of claim 9, further comprising, forming a source connection line electrically connecting the source line patterns with each other.

13. The method of claim 1, wherein at least portion of the conductive isolation patterns is formed using the process of forming the gate line structures.

14. The method of claim 1, further comprising, forming conductive connection pattern electrically connecting the conductive isolation patterns with each other.

15. The method of claim 1, further comprising, forming variable resistance structures on the lower contact plugs, respectively,
wherein each of the variable resistance structures comprises a magnetic tunnel junction.

16-20. (canceled)
